(19) United States
(12) Patent Application Publication
(10) Pub. No.: US 2008/0315246 A1
(43) Pub. Date: Dec. 25, 2008

(54) TRANSISTOR SWITCH CIRCUIT AND SAMPLE-AND-HOLD CIRCUIT

(75) Inventors: Takeshi Ueno, Kawasaki-shi (JP); Shinji Ohtaki, Kawasaki-shi (JP); Tomohiko Ito, Yokohama-shi (JP)

Correspondence Address: AMIN, TUROCY & CALVIN, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/142,075

(22) Filed: Jun. 19, 2008

(30) Foreign Application Priority Data
Jun. 22, 2007 (JP) 2007-165483

(51) Int. Cl. H01L 29/68; H03K 17/00

(52) U.S. Cl. 257/133; 327/96; 257/E29.169

(57) ABSTRACT

A transistor switch circuit includes: a MOS transistor in which a channel is formed when a gate-source voltage is zero; and a voltage supply part which is connected to a gate of the MOS transistor to supply the gate with a voltage for turning off the MOS transistor.

### CROSS REFERENCE TO RELATED APPLICATIONS

This application is based upon and claims the benefit of priority from the prior Japanese Patent Application No. 2007-165483, filed on Jun. 22, 2007; the entire contents of which are incorporated herein by reference.

### BACKGROUND

1. Field of the Invention

The present invention relates to a transistor switch which is designed with reliability of its ON/OFF characteristic change taken into consideration, and to a sample-and-hold circuit using the same.

2. Description of the Related Art

As a transistor switch circuit in a sample-and-hold circuit and the like, used is, for example, an enhancement-mode MOS transistor which turns off when a gate-source voltage is zero and which turns on when the gate-source voltage is equal to a threshold voltage or higher. As an example of such a transistor switch circuit, Mohamed Dessouky and Andreas Kaiser, “Very Low-Voltage Digital-Audio ΔΣModulator with 88-dB Dynamic Range Using Local Switch Bootstrapping” (IEEE JOURNAL OF SOLID-STATE CIRCUITS, VOL. 36, NO. 3, March 2001) discloses an art in which a voltage across a pre-charged capacitor is used to apply a gate-source voltage for turning on a transistor. In this disclosed art, it is possible to realize a sufficiently low on-resistance of the transistor by setting a charging voltage of the capacitor sufficiently high.

Generally, an on-resistance of a MOS transistor depends on its size, and the larger its size is, the lower the on-resistance can be. However, increasing the size of the MOS transistor results in a higher parasitic capacitance expected from a gate terminal, and therefore, when the aforesaid capacitor is provided, its charge flows into the parasitic capacitance, resulting in a reduction in the charging voltage. Therefore, an on-resistance with a desired small value cannot be sometimes realized.

Mathew L, et. al., CMOS Vertical Multiple Independent Gate Field Effect Transistor (MIGFET) (2004 IEEE International SOI Conference, On page(s): 187-189 Publication Date: 4-7 Oct. 2004) discloses a MOS transistor having a plurality of gate terminals usable in the art disclosed in the present application.

### BRIEF SUMMARY OF THE INVENTION

It is an object of the present invention to provide a transistor switch circuit in which reliability of its on/off characteristic change can be improved and to provide a sample-and-hold circuit using the same.

A transistor switch circuit according to an aspect of the present invention includes: a MOS transistor in which a channel is formed when a gate-source voltage is zero; and a voltage supply part connected to a gate of the MOS transistor to supply the gate with a voltage for turning off the MOS transistor.

That is, this transistor switch circuit uses the MOS transistor in which the channel is formed when the gate-source voltage is zero, and the state where the channel is formed is used as an on-state. Further, the voltage supply part is provided to supply the gate with the voltage for turning off the MOS transistor. With this structure, even when the voltage for turning off the MOS transistor varies or fluctuates, a drain-source resistance can be kept high as is necessary in a normal circuit. On the other hand, low resistance in the on-state is not influenced. Therefore, reliability of an on/off characteristic change can be improved.

A sample-and-hold circuit according to another aspect of the present invention includes: a differential amplifier circuit having a pair of differential input terminals and a pair of differential output terminals; a first and a second sampling capacitors connected to the pair of differential input terminals respectively; a first and a second switch circuits via which electric charges are input to the first and second sampling capacitors respectively; and a third and a fourth switch circuits which are connected to the pair of differential output terminals of the differential amplifier circuit respectively and via which voltages generated by the first and second sampling capacitors based on the electric charges are output to the pair of differential output terminals of the differential amplifier circuit respectively, wherein each of the first, second, third, and fourth switch circuits includes: a MOS transistor in which a channel is formed when a gate-source voltage is zero; and a voltage supply part connected to a gate of the MOS transistor to supply the gate with a voltage for turning off the MOS transistor.

In this sample-and-hold circuit, the aforesaid transistor switch circuit is used.

### BRIEF DESCRIPTION OF THE DRAWINGS

FIG. 1 is a schematic diagram showing the structure and operation principle of a transistor switch circuit according to an embodiment;

FIG. 2 is a characteristic chart of a drain-source resistance of the MOS transistor shown in FIG. 1 (comparison with an enhancement-mode MOS transistor);

FIG. 3 is a graph showing the characteristic of the drain-source resistance shown in FIG. 2 in more detail;

FIG. 4 is a circuit diagram showing a MOS transistor usable in a transistor switch circuit according to another embodiment and its usage state;

FIG. 5 is a schematic diagram showing the structure and operation principle of a transistor switch circuit according to still another embodiment;

FIG. 6 is a circuit diagram showing the structure for realizing the operation principle shown in FIG. 5;

FIG. 7 is a circuit diagram additionally showing a concrete structure example of a bootstrap circuit shown in FIG. 1;

FIG. 8 is a circuit diagram additionally showing a more concrete example of the bootstrap circuit shown in FIG. 7;

FIG. 9 is a schematic diagram showing the structure of a transistor adoptable as nMOS transistors MN2, MN3, MN4, MN6, MN7 shown in FIG. 8; and

FIG. 10 is a circuit diagram showing the structure of a sample-and-hold circuit according to an embodiment.

### DETAILED DESCRIPTION OF THE INVENTION

A possible structure as an embodiment in the above-described first aspect is such that the MOS transistor further has a second gate in addition to the aforesaid gate and a threshold voltage changes depending on a voltage applied to the second gate, and the transistor switch circuit further includes a second voltage supply part connected to the second gate of the MOS transistor to supply the second gate with a second voltage with which the channel is formed when the gate-source voltage is zero.

This is an embodiment where a MOS transistor having two gates is used. One of the two gates functions as a normal gate, and the other gate is used as a gate to which the voltage is supplied to fix the characteristic of the MOS transistor that the channel is formed when the gate-source voltage is zero.

A possible structure here is such that when the voltage for turning off the MOS transistor is supplied to the gate of the MOS transistor, the second voltage supply part further supplies the second gate of the MOS transistor with a third voltage for making a drain-source resistance higher than that when the second voltage is supplied to the second gate.

This is also an embodiment where a MOS transistor having two gates is used, but this embodiment has a period during which the third voltage different from the aforesaid second voltage is applied as part of the voltage to the second gate. The third voltage is set as a voltage for increasing the drain-source resistance and is applied while the MOS transistor is turned off. This can further improve reliability of the on/off characteristic change.

As an embodiment, the voltage supply part can have: a charge storage capacitor; and a switching circuit which switches connection so as to cause a voltage generated by the capacitor to be supplied as the voltage to the gate of the MOS transistor. This is a concrete structure example of the voltage supply part. In the charge storage capacitor, the same voltage as a power supply voltage, for instance, can be stored as charge, and the switching circuit causes the voltage stored as the charge to be supplied to the gate of the MOS transistor. Even when the voltage stored as the charge is reduced due to a parasitic capacitance of the gate, a drain-source resistance can be kept high as is necessary in a normal circuit. This can improve reliability of the on/off characteristic change.

A possible structure here is such that the switching circuit includes a plurality of MOS transistors, and at least one of the plural MOS transistors has a first semiconductor region in which a channel is formed, a second semiconductor region which functions as a source and is substantially equal in potential to the first semiconductor region, and another second semiconductor region which is provided between a semiconductor substrate and the first semiconductor region in which the channel is formed and which is different in conductive type from the first semiconductor region and the semiconductor substrate. In other words, this is an embodiment where at least one of the plural MOS transistors in the switching circuit has the semiconductor region as a channel formation region which is electrically separated from the semiconductor substrate. In such a structure, a current does not flow to the semiconductor substrate regardless of the potential of the source, and a normal operation is obtained in a wider range.

Another possible structure here is such that the switching circuit includes a plurality of MOS transistors, and at least one of the plural MOS transistors has an insulation layer between a semiconductor substrate and a semiconductor region in which a channel is formed. In this case, a current does not flow to the semiconductor substrate, either, regardless of the potential of the source, and therefore, a normal operation is obtained in a wider range.

### FIRST EMBODIMENT

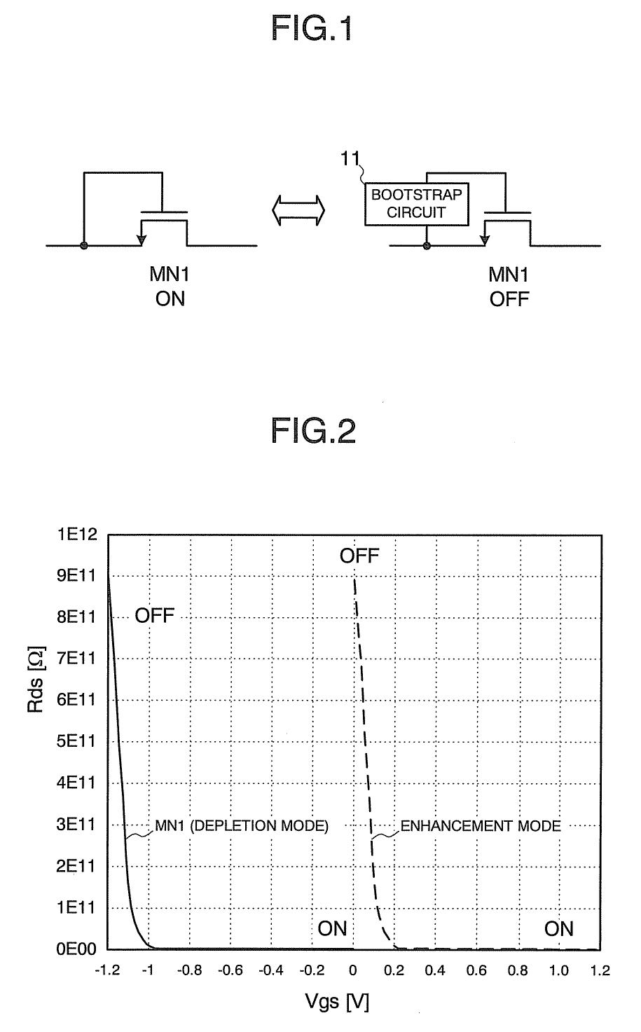

Based on the above, an embodiment will be hereinafter described with reference to the drawings. FIG. 1 shows the structure and operation principle of a transistor switch circuit according to an embodiment. As shown in FIG. 1, an NMOS transistor MN1 is prepared as a switch. The transistor MN1 is a switch presenting a high drain-source resistance (off) and a low drain-source resistance (on). The transistor MN1 is a so-called depletion-mode MOS transistor and is of a type in which a channel is formed between the drain and source when a gate-source voltage is zero.

To turn on the transistor MN1, its gate and source are brought into continuity with each other as shown on the left in FIG. 1, and to turn off the transistor MN1, the gate is connected to a bootstrap circuit 11 (voltage supply part) generating a voltage for turning off the transistor MN1 as shown on the right in FIG. 1. An example of the structure necessary for such an on/off change will be described later.

The bootstrap circuit 11 supplies the gate with the voltage for turning off the transistor MN1, that is, a voltage with which the gate comes to have a sufficiently minus voltage relative to a voltage of the source. A concrete structure example of the bootstrap circuit 11 will be described later.

FIG. 2 shows a characteristic of a drain-source resistance of the MOS transistor MN1 shown in FIG. 1 (comparison with the characteristic of an enhancement-type MOS transistor) (according to simulations). A gate-source voltage Vgs is taken on the horizontal axis and a drain-source resistance Rds is taken on the vertical axis. In the transistor MN1, the drain-source resistance is low when zero volt is applied as the gate-source voltage, which is an on-state, while the drain-source resistance becomes high when a certain degree of minus voltage is applied as the gate-source voltage, which is an off-state. This is a characteristic of a depletion-mode transistor.

On the other hand, in the so-called enhancement-mode MOS transistor, the drain-source resistance is high when zero volt is applied as the gate-source voltage as shown in FIG. 2, which is an off-state, while the drain-source resistance becomes low when a certain degree of plus voltage (equal to a threshold voltage or higher) is applied as the gate-source voltage, which is an on-state.

In a switch circuit using the enhancement-mode transistor, for example, the bootstrap circuit 11 shown in FIG. 1 can be structured to supply the gate with a voltage for turning on the transistor, that is, a voltage with which the gate comes to have a sufficiently plus voltage relative to a voltage of the source. For example, it is assumed here that the bootstrap circuit 11 is designed to supply a voltage with which the gate comes to have a +1.2 V voltage relative to the voltage of the source. For example, it is further assumed that the drain-source resistance (that is, on-resistance) becomes 116Ω when the gate voltage relative to the voltage of the source is +1.2 V as designed.

In general, the lower the on-resistance, the more preferable, but in order to realize a low on-resistance, a transistor has to have a large size (gate width). However, increasing this size increases a gate input capacitance (due to a parasitic capacitance or the like between the gate and drain). Due to the gate input capacitance, a current flows to the gate input capacitance even when the voltage supplied by the bootstrap circuit 11 is +1.2 V relative to the voltage of the source as designed, and consequently, an actual voltage generated by the bootstrap circuit 11 lowers. Therefore, if the voltage of the gate relative to the voltage of the source is lowered to +0.8 V, the drain-source resistance (that is, on-resistance) in this case increases up to, for example, 824Ω. Therefore, reliability of the on/off characteristic change deteriorates.

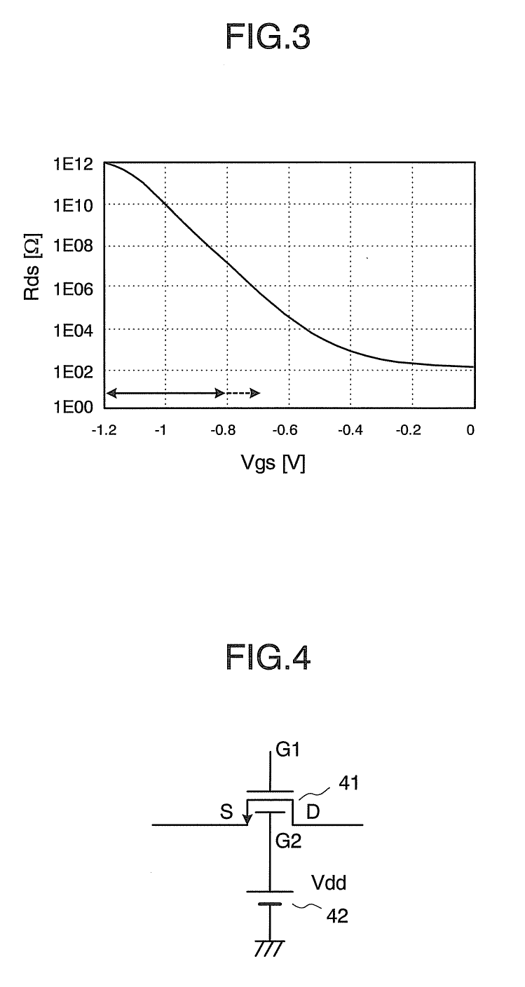

FIG. 3 shows the characteristic of the drain-source resistance shown in FIG. 2 in more detail (the vertical axis is a log scale). In the switch circuit using the depletion-mode MOS transistor, the bootstrap circuit 11 shown in FIG. 1 is structured to supply the gate with the voltage for turning off the transistor MN1, that is, the voltage with which the gate comes to have a minus voltage relative to the voltage of the source. For example, it is assumed here that the bootstrap circuit 11 is designed to supply a voltage with which the gate comes to have a −1.2 V voltage relative to the voltage of the source. As shown in FIG. 3, when the gate has the −1.2V voltage relative to the voltage of the source as designed, the drain-source resistance (that is, off-resistance) is, for example, 900 GΩ.

It is assumed here that, taking the influence of the aforesaid gate input capacitance into account, the current flows to the gate input capacitance and an actual gate voltage becomes −0.8 V relative to the voltage of the source. In this case, as shown in FIG. 3, the drain-source resistance (that is, off-resistance) still keeps a large value even though being reduced to 14 MΩ. If the influence of the gate input capacitance is larger and the actual gate voltage becomes, for example, −0.7 V relative to the voltage of the source, the off-resistance is about 1 MΩ, which means that a value that can be said to be a normal insulation resistance is ensured. Naturally, there is no influence on the on-resistance.

Therefore, the gate drive capability that the bootstrap circuit 11 needs to have in order to ensure reliability of the on/off characteristic change may be lower than that of a bootstrap circuit of a switch circuit using the enhancement-mode transistor. Further, actually, the parasitic capacitance of the transistor MN1 in the off-state is smaller than that in the on-state, which means that the gate drive capability of the bootstrap circuit 11 may be still lower.

As described above, according to this embodiment, even when the gate drive capability of the bootstrap circuit 11 is low, it is possible to improve reliability of the on/off characteristic change. Further, since the drive capability can be reduced, the area occupied by the bootstrap circuit 11 in an integrated circuit can be made smaller than that in the switch circuit using the enhancement-mode transistor, which results in cost reduction.

Though FIG. 1 shows the transistor switch circuit using the nMOS transistor MN1, it is possible to provide a bootstrap circuit in a transistor switch circuit using a pMOS transistor, based on the similar principle. In this case, the switch uses the PMOS transistor in which a channel is formed between a drain and a source when a gate-source voltage is zero, and in order to turn off this pMOS transistor, the bootstrap circuit is designed to supply the gate with a voltage with which the gate comes to have a plus voltage relative to the voltage of the source.

### SECOND EMBODIMENT

Next, FIG. 4 shows a MOS transistor usable in a transistor switch circuit according to another embodiment and its usage state. In this embodiment, a MOS transistor 41 having two gates G1, G2 is used as a transistor serving as a switch. Further, this MOS transistor 41 is used in such a manner that a voltage Vdd of, for example, a voltage source 42 (second voltage supply part) is constantly applied to the gate G2. The transistor 41 as structured and used in such a manner is used in place of the transistor MN1 shown in FIG. 1.

The two gates G1, G2 of the nMOS transistor 41 are independently controllable from an external part, and the nMOS transistor 41 is structured such that a source region, a drain region, a first gate region, and a second gate region each in a columnar shape are formed on a semiconductor substrate, and a channel region is provided between the source region and the drain region. The channel region is controlled by the gate G1 and the gate G2. Such a MOS transistor is called FinFET and is disclosed in, for example, the previously cited reference by Mathew L, et. al.

In the MOS transistor 41, by increasing/decreasing a voltage applied to the gate G2, it is possible to change a threshold voltage when the gate G1 functions as a normal gate. When the high voltage Vdd is applied to the gate G2 as shown in FIG. 4, the threshold voltage decreases, and when the gate G1 is made to function as the normal gate, the MOS transistor 41 can have the characteristic of a depletion-mode MOS transistor. Therefore, the MOS transistor 41 can be used in place of the transistor MN1 shown in FIG. 1.

Needless to say, this embodiment is also applicable when the MOS transistor having the two gates is a pMOS transistor. In this case, a low voltage (for example, a ground voltage) is applied to the gate G2 to change the threshold voltage so that the pMOS transistor has the characteristic of the depletion-mode MOS transistor.

### THIRD EMBODIMENT

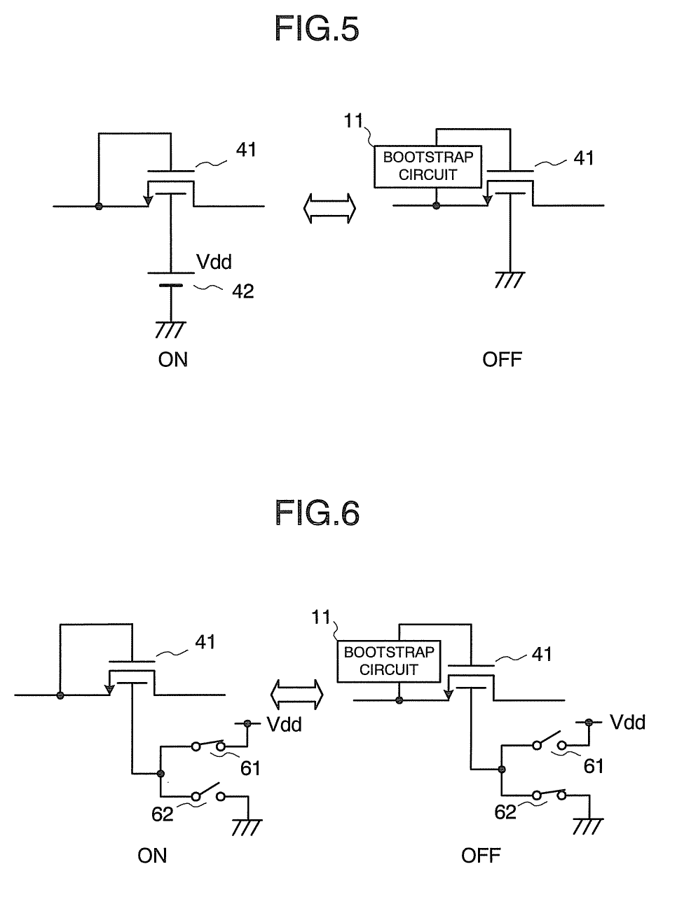

Next, FIG. 5 shows the structure and operation principle of a transistor switch circuit according to still another embodiment. In FIG. 5, the same constituent elements as those already described and shown in the drawings are denoted by the same reference numerals and symbols. Redundant description of these elements will be omitted.

As shown in FIG. 5, the nMOS transistor 41 (described in FIG. 4) is prepared as a switch. To turn on the transistor 41, its gate and source are brought into continuity with each other and the high voltage (Vdd) is applied to the second gate as shown on the left in FIG. 5. To turn off the transistor 41, the bootstrap circuit 11 (voltage supply part) generating the voltage for turning off the transistor 41 is connected to the gate and the low voltage (ground) is applied to the second gate as shown on the right in FIG. 5. A structure example necessary for this on/off change will be described later. Further, a concrete structure example of the bootstrap circuit 11 will also be described later.

According to such a transistor switch circuit, since the low voltage is applied to the second gate when the transistor switch circuit is off, the threshold voltage increases in the plus direction, that is, the drain-source resistance increases. Therefore, it is possible to further improve reliability of the on/off characteristic change. In other words, the gate drive capability of the bootstrap circuit 11 may be still lower than that in the case of the embodiment shown in FIG. 1. Therefore, the area occupied by the bootstrap circuit 11 in an integrated circuit can be reduced more than in the case shown in FIG. 1, which results in further cost reduction.

Needless to say, the structure shown in FIG. 5 is applicable when the MOS transistor having the two gates is a pMOS transistor. In this case, the state where the low voltage (for example, the ground voltage) is applied to the gate G2 is used as the on-state of the transistor switch, and the state where the high voltage (for example, the power supply voltage) is applied to the gate G2 is used as the off-state of the transistor switch.

FIG. 6 shows the structure for realizing the operation principle shown in FIG. 5. In FIG. 6, the same constituent elements as those shown in FIG. 5 will be denoted by the same reference numerals and symbols, and description thereof will be omitted. In FIG. 6, switches 61, 62 are provided in order to apply either the power supply voltage Vdd or the ground voltage (third voltage) to one of the gates of the MOS transistor 41 having the two gates, depending on whether the MOS transistor 41 is to be turned on or turned off.

The switch 61 is inserted and connected between the power supply voltage Vdd and the second gate, and it is controlled to be on when the transistor 41 is to be turned on, and is controlled to be off when the transistor 41 is to be turned off. The switch 62 is inserted and connected between the ground voltage and the second gate, and contrary to the above, it is controlled to be off when the transistor 41 is to be turned on, and is controlled to be on when the transistor 41 is to be turned off. A concrete example usable as each of the switches 61, 62 is a switch using a MOS transistor.

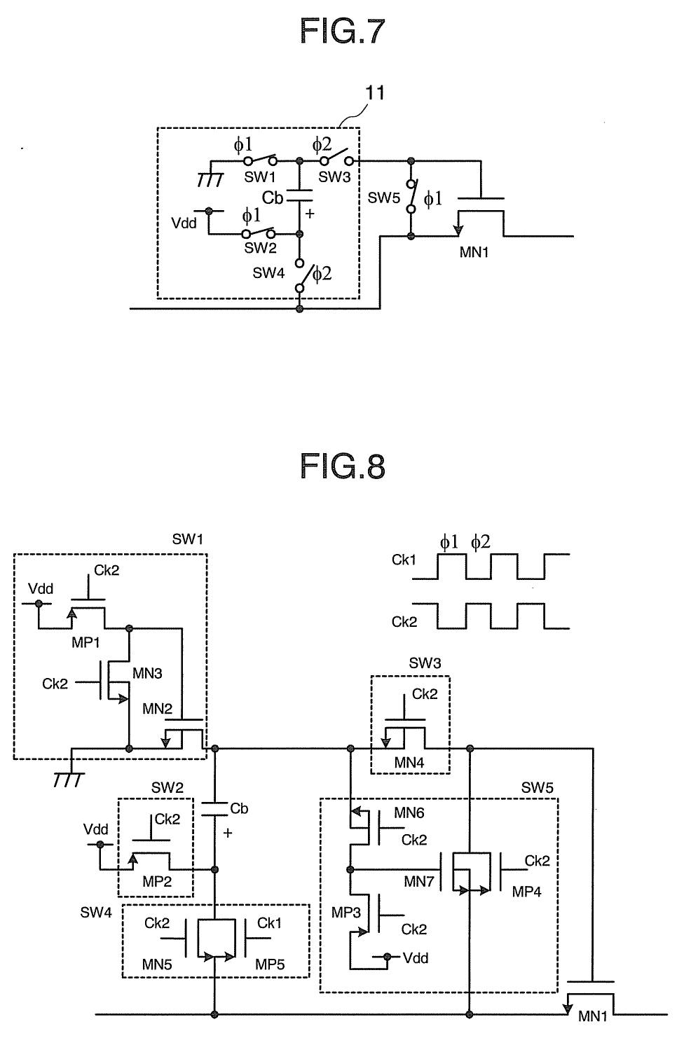

Next, FIG. 7 additionally shows a concrete structure example of the bootstrap circuit 11 shown in FIG. 1. In FIG. 7, the same constituent elements as those already described and shown in the drawings will be denoted by the same reference numerals and symbols, and description thereof will be omitted. As shown in FIG. 7, the bootstrap circuit 11 has switches SW1, SW2, SW3, SW4 and a capacitor Cb. Further, a switch SW5 is provided to bring the gate and source into continuity with each other when the transistor MN1 is to be turned on. Though the transistor MN1 is an NMOS transistor in the structure example shown in FIG. 7, the similar principle is of course applicable when the transistor MN1 is a PMOS transistor.

Switching operations of the switches SW1, SW2, SW5 are simultaneously controlled (φ1), and switching operations of the switches SW3, SW4 are simultaneously controlled in opposite phase to the above (φ2). When the switches SW1 to SW5 are at switching positions as shown in FIG. 7, the gate and source of the transistor MN1 are connected by the switch SW5, and therefore, the transistor MN1 is on. In addition, in this on-period, the switches SW2, SW1 are on, and therefore, a current path from the power supply voltage Vdd to the ground via the switch SW2, the capacitor Cb, and the switch SW1 is established. Accordingly, the capacitor Cb is charged so that its upper terminal in FIG. 7 becomes a negative side. The capacitor Cb is thus charged irrespective of the voltage states of the gate and source of the transistor MN1 because the switches SW3, SW4 are off.

Next, when the switches SW1 to SW5 are controlled to opposite switching positions, a voltage generated by the charging of the capacitor Cb is applied between the source and gate of the transistor MN1. This is because a lower terminal in FIG. 7 of the capacitor Cb is connected to the source of the transistor MN1 via the switch SW4 and the upper terminal in FIG. 7 of the capacitor Cb is connected to the gate of the transistor MN1 via the switch SW3. That is, in the transistor MN1, a voltage with which the gate comes to have a minus voltage relative to the voltage of the source is applied. Consequently, the transistor MN1 becomes off. In this state, since the switches SW1, SW2, SW5 are switched to off, no other operation occurs except the operation in which the voltage of the capacitor Cb is applied between the source and gate of the transistor MN1.

In the bootstrap circuit 11 as structured above, a capacitance value of the capacitor Cb can be considerably lowered, which realizes a reduction in the capability for driving the gate of the transistor MN1. The area that the capacitor needs to have in an integrated circuit is generally far larger than that of an active element, and therefore, if this capacitance value can be small, the area occupied by the bootstrap circuit 11 in the integrated circuit can be effectively reduced. A concrete example usable as each of the switches SW1 to SW5 is a switch using a MOS transistor.

Next, FIG. 8 additionally shows a more concrete structure example of the bootstrap circuit 11 shown in FIG. 7. In FIG. 8, the same constituent elements as those already described and shown in the drawings are denoted by the same reference numerals and symbols. In FIG. 8, a clock Ck1 and a clock Ck2 are in opposite phases, and swing between the ground and the power supply voltage (Vdd). Though in this structure example, the transistor MN1 is an nMOS transistor, it goes without saying that the similar structure is applicable also when the transistor MN1 is a PMOS transistor.

In the switch SW1, when Ck2 is high (φ2), a transistor MP1 turns off, a transistor MN3 turns on, and a transistor MN2 as a main body of the switch turns off. In the switch SW2, when Ck2 is high (φ2), a transistor MP2 turns off. In the switch SW3, when Ck2 is high (φ2), a transistor MN4 turns on. In the switch SW4, when Ck2 is high and Ck1 is low (φ2), either the transistor MN5 or the transistor MP5 turns on, and consequently the switch SW4 turns on. When a source potential of the transistor MN1 is high, the transistor MN5 may not sometimes turn on even when Ck2 is high, and therefore, in this case, the transistor MP5 is turned on owing to the low level of Ck1.

Further, in the switch SW5, when Ck2 is high (φ2), a transistor MP4 turns off, and in addition, a transistor MN6 turns on and a transistor MP3 turns off, and therefore, a transistor MN7 also turns off. The connection between a source of the transistor MN6 and the upper electrode in FIG. 8 of the capacitor Cb is not shown in FIG. 7, but this connection is a connection in order to surely cause the off-state by lowering the gate voltage of the transistor MN7.

In the switch SW5, when Ck2 is low (φ1), the transistor MN6 turns off (because its source is connected to the ground via MN2) and the transistor MP3 turns on and accordingly the transistor MN7 or the transistor MP4 turns on. Also in this case, when the source potential of the transistor MN1 is high, the transistor MN7 may not sometimes turn on even though Ck2 is low, and in such a case, the transistor MP4 is turned on owing to the low level of Ck2.

In the structure example shown in FIG. 8, the NMOS transistors MN2, MN3, MN4, MN6, MN7 are connected so that their sources and back gates (bodies) have substantially the same potential, as shown by the signs. A semiconductor region which serves as the back gate is a region where the channel is formed, and each of the transistors MN2, MN3, MN4, MN6, MN7 is a transistor in which this region is electrically insulated from the semiconductor substrate. In the transistor having such a structure, the source (n-region) and the semiconductor substrate (p-region) are never forward-biased, which can widen a range of the voltage of the source operating as the transistor.

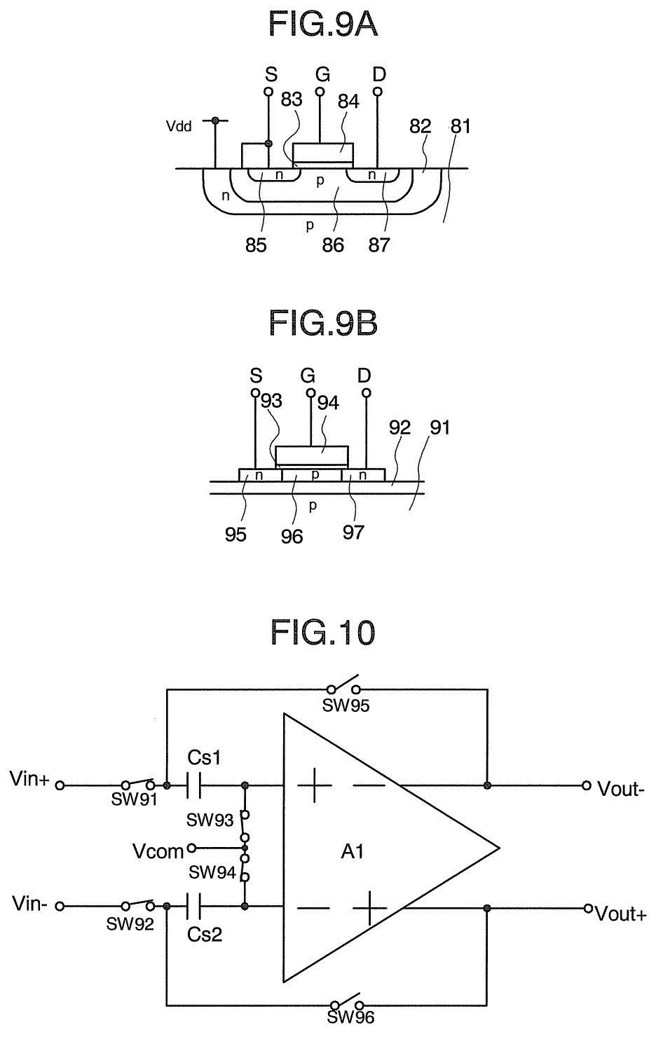

FIG. 9A and FIG. 9B are schematic diagrams showing the structures of transistors adoptable as the nMOS transistors MN2, MN3, MN4, MN6, MN7 shown in FIG. 8 (the structures in FIG. 9A and FIG. 9B are both adoptable). The transistor shown in FIG. 9A is a so-called triple-well MOS transistor, and the transistor shown in FIG. 9B is a MOS transistor using SOI as the semiconductor substrate.

The structure shown in FIG. 9A has a semiconductor substrate 81 (p-type), a semiconductor region 82 (n-type), a gate insulation film 83, a gate electrode 84, a source region 85 (n-type), a body (back gate; channel formation region) 86 (p-type), and a drain region 87 (n-type). The body 86 which is a semiconductor region where a channel is formed and the semiconductor substrate 81 are separated from each other by the semiconductor region 82 different in conductive type from the body 86 and the semiconductor substrate 81. The semiconductor region 82 is connected to a high voltage (for example, the power supply voltage Vdd). Accordingly, pn junctions in contact with the semiconductor region 82 are reverse-biased, which prevents a current from flowing to the semiconductor substrate 81.

The structure shown in FIG. 9B has a semiconductor substrate 91 (p-type), an insulation layer 92, a gate insulation film 93, a gate electrode 94, a source region 95 (n-type), a channel formation region 96 (p-type), and a drain region 97 (n-type). Among them, the insulation layer 92 is an insulation layer provided on the semiconductor substrate 91 in advance. A MOS transistor is formed on the insulation layer 92. This can prevent a current from flowing to the semiconductor substrate 91.

### FOURTH EMBODIMENT

Next, FIG. 10 shows the structure of a sample-and-hold circuit according to an embodiment. The sample-and-hold circuit is structured such that its positive input Vin+ is connected to a positive input of a differential amplifier circuit A1 and a switch circuit SW93 via a switch circuit SW91 and a sampling capacitor Cs1. Further, its negative input Vin− is connected to a negative input of the differential amplifier circuit A1 and a switch circuit SW94 via a switch circuit SW92 and a sampling capacitor Cs2. The other sides of SW93 and SW94 are connected to a common potential Vcom. Further, a switch circuit SW95 is connected between a connection node of SW91 and Cs1 and a negative output of the differential amplifier circuit A1, and a switch circuit SW96 is connected between a connection node of SW92 and Cs2 and a positive output of the differential amplifier circuit A1. As each of the switch circuits SW91 to SW96, the transistor switch circuit described above is usable.

The sample-and-hold circuit operates in the following manner. At switching positions of the switch circuits SW91 to SW96 in FIG. 10, the sampling capacitor Cs1 is charged with a voltage led to Vin+, and the sampling capacitor Cs2 is charged with a voltage led to Vin− (sampling). Next, when the switch circuits SW91 to SW96 in FIG. 10 are switched to the opposite positions, voltages generated when the sampling capacitors Cs1, Cs2 are charged occurs and are held at the output terminals Vout+, Vout− of the differential amplifier circuit A1 (hold).

According to such a sample-and-hold circuit, since reliability of the on/off characteristic change of the switch circuits SW91 to SW96 is improved, more accurate voltage sampling and holding are realized. In particular, in the switch circuits SW91, SW92, SW95, SW96, their on-resistances are low and constant irrespective of changes of the transmitted voltages, and therefore, the adoption of the above-described transistor switch circuit provides a great effect.

It should be noted that the present invention is not limited to the exact forms described in the above embodiments, and the constituent elements can be modified and embodied without departing from the spirit of the invention when the invention is embodied. Further, it is possible to form various inventions by appropriately combining a plurality of constituent elements disclosed in the above-described embodiments. For example, some of all the constituent elements shown in the embodiments may be deleted. Further, constituent elements in different embodiments may be appropriately combined.

According to the present invention, it is possible to provide a transistor switch circuit in which reliability of an on/off characteristic change can be improved, and a sample-and-hold circuit using the same.

What is claimed is:

1. A transistor switch circuit comprising:
a MOS transistor in which a channel is formed when a gate-source voltage is zero; and
a voltage supply part connected to a gate of the MOS transistor to supply the gate with a voltage for turning off the MOS transistor.

2. The transistor switch circuit according to claim 1,
wherein the MOS transistor further has a second gate and a threshold voltage changes depending on a voltage applied to the second gate; and
wherein the transistor switch circuit further comprising a second voltage supply part connected to the second gate of the MOS transistor to supply the second gate with a second voltage with which the channel is formed when the gate-source voltage is zero.

3. The transistor switch circuit according to claim 2,
wherein when the voltage for turning off the MOS transistor is supplied to the gate of the MOS transistor, the second voltage supply part further supplies the second gate of the MOS transistor with a third voltage for making a drain-source resistance higher than that when the second voltage is supplied to the second gate.

4. The transistor switch circuit according to claim 1,
wherein the voltage supply part has:
a charge storage capacitor; and
a switching circuit which switches connection so as to cause a voltage generated by the capacitor to be supplied as the voltage to the gate of the MOS transistor.

5. The transistor switch circuit according to claim 4,
wherein the switching circuit includes a plurality of MOS transistors, and at least one of the plural MOS transistors has a first semiconductor region in which a channel is formed, a second semiconductor region which functions as a source and is substantially equal in potential to the first semiconductor region, and another second semiconductor region which is provided between a semiconductor substrate and the first semiconductor region where the channel is formed and which is different in conductive type from the first semiconductor region and the semiconductor substrate.

6. The transistor switch circuit according to claim 4,
wherein the switching circuit includes a plurality of MOS transistors, and at least one of the plural MOS transistors has an insulation layer between a semiconductor substrate and a semiconductor region in which a channel is formed.

7. A sample-and-hold circuit, comprising:
a differential amplifier circuit having a pair of differential input terminals and a pair of differential output terminals;
a first and a second sampling capacitor connected to the pair of differential input terminals respectively;
a first and a second switch circuit via which electric charges are input to the first and second sampling capacitors respectively; and
a third and a fourth switch circuit which are connected to the pair of differential output terminals of the differential amplifier circuit respectively and via which voltages generated by the first and second sampling capacitors based on the electric charges are output to the pair of differential output terminals of the differential amplifier circuit respectively,
wherein each of the first, second, third, and fourth switch circuits includes:
a MOS transistor in which a channel is formed when a gate-source voltage is zero; and
a voltage supply part connected to a gate of the MOS transistor to supply the gate with a voltage for turning off the MOS transistor.
